(19) United States
(12) Patent Application Publication
(10) Pub. No.: US 2006/0000505 A1
(43) Pub. Date: Jan. 5, 2006

(54) Photovoltaic cell and method for manufacturing the same

(75) Inventors: Iwao Hayashi, Hiratsuka-shi (JP); Toshimitsu Muramatsu, Hiratsuka-shi (JP); Junichi Mogi, Hiratsuka-shi (JP); Hideo Kogure, Hiratsuka-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KANSAI PAINT CO., LTD., Amagasaki-shi (JP)

(21) Appl. No.: 11/138,742

(22) Filed: May 25, 2005

(30) Foreign Application Priority Data
May 26, 2004 (JP) 2004-155513

(51) Int. Cl. H01L 31/00

(52) U.S. Cl. 136/263; 136/244; 136/251; 438/82; 438/80

(57) ABSTRACT

A photovoltaic cell having a transparent first substrate (61) having semiconductor electrodes (7) supporting a photosensitizing dye, a second substrate (62) having counter electrodes (4) disposed so as to face the semiconductor electrodes (7), and an electrolyte layer disposed between the semiconductor electrode (7) and the counter electrode (4); the electrolyte layer (1) being sealed by a sealing member (2) lying between the first substrate (61) and the second substrate (62); the first substrate (61), the second substrate (62) and the sealing member (2) being formed of similar materials, and the portions of the first substrate and the second substrate that are in contact with the sealing member (2) being ultrasonically welded to the sealing member. This photovoltaic cell can maintain excellent cell performance for a long time.

### TECHNICAL FIELD

The present invention relates to a photovoltaic cell and a method for manufacturing the same. In particular, the present invention relates to a dye-sensitized photovoltaic cell and a manufacturing method therefore.

### BACKGROUND ART

In recent years, dye-sensitized solar cells that can achieve a high photoelectric conversion efficiency at low cost have been attracting public attention as photovoltaic cells. Such dye-sensitized solar cells usually comprise a semiconductor electrode obtained by sintering metallic oxide particles on a transparent conductor layer disposed on a substrate; a counter electrode in which a conductor layer is formed on another substrate; and a charge transfer layer disposed between the semiconductor electrode and the counter electrode, wherein the semiconductor electrode supports a photosensitizing dye (for example, Japanese Unexamined Patent Publication Nos. 1989-220380 and 2003-187883). In such a photovoltaic cell, an electric current is generated by repeating the operation such that light incident from the outer surface of the semiconductor electrode excites the photosensitizing dye, so that the photosensitizing dye promptly transfers electrons to the semiconductor electrode, while the photosensitizing dye that has lost electrons receives electrons from ions in the charge transfer layer, and the molecules in the charge transfer layer that have transferred electrons therefrom receive electrons from the counter electrode.

In the above-described photovoltaic cell, since an electrolytic solution is usually used for the charge transfer layer, the charge transfer layer is sealed between electrodes with a sealing member so that the electrolytic solution does not leak out. As a material for the sealing member, for example, a hot melt resin as disclosed in Japanese Unexamined Patent Publication No. 2003-187883, is usually used and the sealing member is sealed by thermocompression bonding.

However, because photovoltaic cells are used outdoors in most cases, weather resistance is required, while ethylene carbonate, acetonitrile and similar low molecular weight solvents that easily evaporate are often used as the solvent for the electrolyte. Therefore, in a device having a prior art structure, it is impossible to satisfactorily seal the electrolytic solution and therefore the electrolytic solution gradually leaks out. This causes deterioration of the cell performance with time.

### DISCLOSURE OF THE INVENTION

An object of the present invention is to provide a photovoltaic cell that maintains excellent cell performance over a long period, and a method for manufacturing such a photovoltaic cell.

This object of the present invention can be achieved by a photovoltaic cell comprising a transparent first substrate having a semiconductor electrode supporting a photosensitizing dye, a second substrate having a counter electrode disposed so as to face the semiconductor electrode; and an electrolyte layer disposed between the semiconductor electrode and the counter electrode, the electrolyte layer being sealed by a sealing member lying between the first substrate and the second substrate, the first substrate, the second substrate and the sealing member being formed of similar materials, and the portions of the first substrate and the second substrate that are in contact with the sealing member being ultrasonically welded to the sealing member.

Another object of the present invention can be achieved by a method for manufacturing a photovoltaic cell, the photovoltaic cell comprising a transparent first substrate having a semiconductor electrode supporting a photosensitizing dye, a second substrate having a counter electrode disposed so as to face the semiconductor electrode, and an electrolyte layer disposed between the semiconductor electrode and the counter electrode, the electrolyte layer being sealed by a sealing member lying between the first substrate and the second substrate, the first substrate, the second substrate and the sealing member being formed of similar materials, and the method for manufacturing the photovoltaic cell comprising an ultrasonic welding step for welding the portions of the first substrate and the second substrate in contact with the sealing member to the sealing member.

### BRIEF DESCRIPTION OF THE DRAWINGS

FIG. 1(a) is a plan view of a photovoltaic cell according to one embodiment of the present invention. FIG. 1(b) and FIG. 1(c) are cross-sectional views taken along the planes of A-A and B-B in FIG. 1(a), respectively.

FIG. 2 is a schematic diagram illustrating one example of an ultrasonic welding process.

### BEST MODE FOR CARRYING OUT THE INVENTION

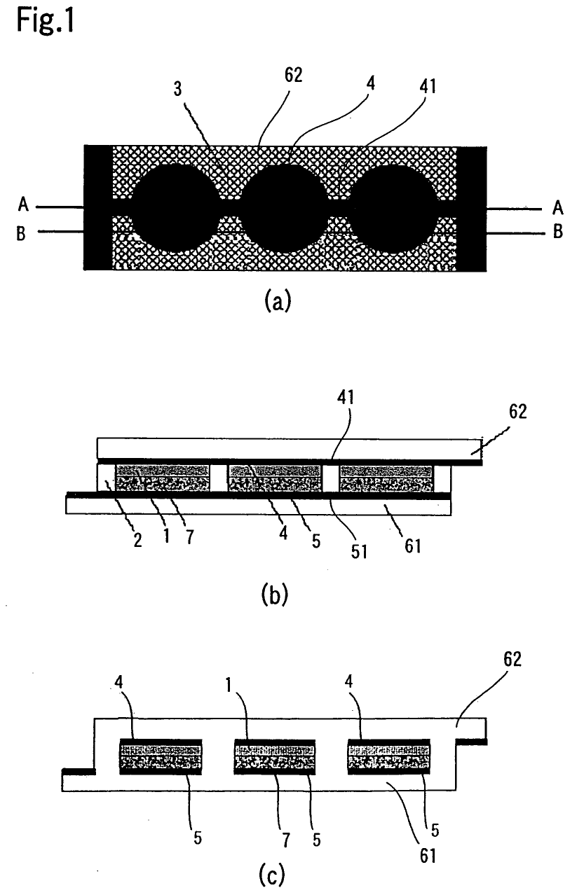

Hereunder, one embodiment of the present invention is explained with reference to the attached drawings. FIG. 1(a) is a plan view of a photovoltaic cell according to this embodiment of the present invention; FIG. 1(b) and FIG. 1(c) are cross-sectional views taken along the planes of A-A and B-B in FIG. 1(a), respectively.

As shown in FIGS. 1(a) to 1(c), in the photovoltaic cell of this embodiment, an electrolyte layer 1 is provided between a substrate (a first substrate) 61, having semiconductor electrodes 7 formed thereon via a conductive layer 5, and a substrate (second substrate) 62, having counter electrodes 4 facing the semiconductor electrodes 7 formed on the surface thereof. In the present embodiment, a plurality of semiconductor electrodes 7 and counter electrodes 4 are formed, and the electrolyte layer 1 is provided between each pair of the semiconductor electrode 7 and the counter electrode 4. Each adjacent pair of semiconductor electrodes 7 and 7 and counter electrodes 4 and 4 are electrically connected through conductive connecting parts 51 and 41, respectively, forming a parallel module. Each electrolyte layer 1 is sealed with a sealing member 2 at a periphery of the region between the substrates 61 and 62. The electric current generated in this photovoltaic cell can be outputted from one of the counter electrode 4 and the conductive layer 5.

The substrates 61 and 62 are transparent and insulative film-like members. Preferable examples of the materials for the substrates 61 and 62 are flexible thermoplastic resins that are suitable for ultrasonic welding. Specific examples of such resins are polymethyl methacrylate, polycarbonates, polystyrene, polyethylene sulfide, polyethersulfones, polyolefins, polyethylene terephthalate, polyethyle nenaphthalate, triacetylcellulose, silicone-based resins, fluorine-based resins, acrylic resins, etc. Among these, at least one member selected from the group consisting of polyethylene terephthalate, silicone-based resins, fluorine-based resins, and acrylic resins can be suitably used, in particular, polyethylene terephthalate is preferable.

The conductive layer 5 is formed of a transparent conductive material. Examples of such materials are metal oxides such as tin oxide, fluorine-doped tin oxide (FTO), indium-doped tin oxide (ITO), zinc oxides doped with fluorine, indium or the like, etc.

The semiconductor electrode 7 is formed of a metal oxide semiconductor and supports a photosensitizing dye. Examples of materials for the semiconductor electrode 7 are oxides of zinc, niobium, tin, titanium, vanadium, indium, tungsten, tantalum, zirconium, molybdenum, manganese and the like. The semiconductor electrode 7 is preferably formed as a porous film on which semiconductor fine particles having a diameter of approximately 5 nm to 200 nm are deposited to increase the amount of the supported photosensitizing dye, and the thickness of such a film is usually approximately 0.1 to 20 μm. After depositing semiconductor fine particles, it is also possible to apply a titanium sol or a peroxotitanium sol formed from a hydrolytic titanium compound, hydrolytic titanium low condensate, titanium hydroxide, titanium hydroxide low condensate, etc., and water may be evaporated by heating after washing, if necessary, to obtain a substance for use as a semiconductor electrode 7.

It is possible to use known dyes for the photosensitizing dye used for dye sensitization in the semiconductor electrode 7. Examples of usable dyes are ruthenium-tris-, ruthenium-bis-, osmium-tris-, and osmium-bis-type transition metal complexes; ruthenium-cis-diaqua-bipyridyl complexes; phthalocyanines, porphyrins, dithiolate complexes, acetylacetonato complexes and like metal chelate complexes; cyanidin dyes, merocyanine dyes, rhodamine dyes and like organic pigments; and organic compounds including an oxadiazole derivative, a benzothiazole derivative, a coumarin derivative, a stilbene derivative, and/or an aromatic ring. It is preferable that these pigments have carboxyl groups, sulfonate groups, phosphate groups, amide groups, amino groups, carbonyl groups, phosphine groups and/or like functional groups so as to be easily chemically adsorbed onto the semiconductor electrode. Such a photosensitizing dye can be adsorbed on and supported by the semiconductor electrode 7 by dissolving the photosensitizing dye in a suitable solvent and dipping the semiconductor electrode 7 in the thus-obtained dye solution.

The counter electrode 4 can be formed of the same material as the conductive layer 5, as well as of platinum, silver, indium and like metals, etc., having a catalytic function such as donating electrons to the electrolyte 1.

There is no limitation on the electrolyte 1 and a liquid electrolyte (electrolytic solution), a gel electrolyte, a molten salt electrolyte, a solid electrolyte, etc., can be used. However, from the viewpoint of obtaining excellent electrical power generation efficiency, it is preferable to use an electrolytic solution. An example of the electrolytic solution is such that iodine/iodide, bromine/bromide, a transition metal complex or like electrolyte is dissolved in a solvent such as acetonitrile, ethylene carbonate, etc.

Examples of the material for the sealing member 2 are the same as for the substrates 61 and 62, and the sealing member 2 is formed so as to seal each electrolyte layer 1 individually. The conductive connecting parts 51 and 41 are formed in the same layers as the conductive layer 5 and the counter electrode 4 respectively. The materials for the conductive connecting parts 51 and 41 may be the same as those for the conductive layer 5 and the counter electrode 4 respectively; however, the conductive connecting parts 51 and 41 may also be formed of silver, aluminum or like metal leads.

An example of a method for manufacturing the above-descried photovoltaic cell is explained below. First, using a material for the conductive layer 5, a film is formed on a substrate 61 by vacuum evaporation, sputtering, etc., and the thus-formed film is patterned into a desired shape to form the conductive layer 5 and the conductive connecting parts 51.

Second, a rectangular sealing member 2 having a plurality of openings is placed on the surface of the substrate 61 (upper part of FIG. 1), and the openings are aligned with the conductive layer 5. Thereafter, a sol solution containing metal oxide fine particles is applied in the openings of the sealing member 2 and dried, forming a semiconductor electrode 7 which is a porous film. Subsequently, the surface of the semiconductor electrode 7 is dipped in a sensitizing dye solution and dried so that photosensitizing dye is supported by the semiconductor electrode 7. By applying an electrolytic solution to the surface of the semiconductor electrode 7, an electrolyte layer 1 is formed.

A film composed of the material for the counter electrode 4 is formed on a substrate 62 by vacuum evaporation, sputtering, etc., and the film is then subjected to patterning, forming a plurality of counter electrodes 4 and conductive connecting parts 41. Thereafter, the substrates 61 and 62 are mated so that each counter electrode 4 corresponds to a semiconductor electrode 7. As the last step, the portions of the substrates 61 and 62 that are in contact with the sealing member 2 are subjected to ultrasonic welding to connect the substrates 61 and 62 to each other through the sealing member 2, completing a photovoltaic cell.

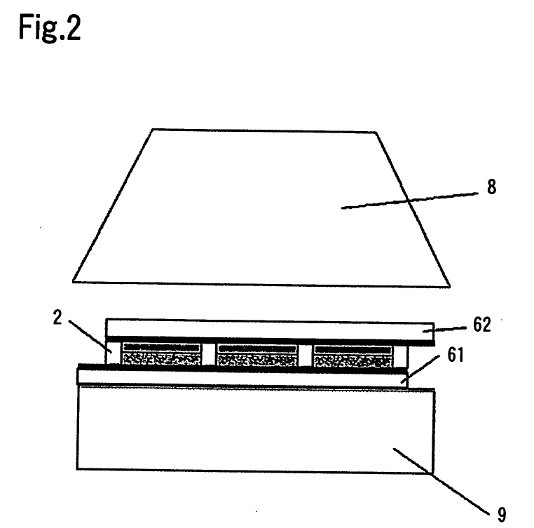

Ultrasonic welding can be conducted using, for example, an apparatus having a structure as shown in FIG. 2. This apparatus comprises a horn 8 that transfers oscillational energy from an oscillator (not shown), and a base 9 on which an object to be welded is laid, wherein protrusions (energy directors) are provided on top of the base 9 so as to concentrate the oscillational energy. The protrusions on the base 9 are provided in a range that corresponds to the configuration of the sealing member 2 (e.g., the region shown as 3 in FIG. 1 (a)). When ultrasonic welding is conducted, the layered substrates 61 and 62 are aligned so that the sealing member 2 corresponds to the protrusions on the base 9, the substrates 61 and 62 are sandwiched between the horn 8 and the base 9 while applying pressure, and ultrasonic oscillation is then applied from the horn 8. Frictional heat is thereby generated in the portions connecting the substrates 61 and 62 to the sealing member 2, and the resin in these portions is welded. Therefore, the substrates 61 and 62 are connected to the sealing member 2. In the present embodiment, ultrasonic oscillation is not directly applied to the conductive connecting parts 51 and 41; however, the sealing member 2 is melted in the vicinity of the conductive connecting parts 51 and 41, and therefore the conductive connecting parts 51 and 41 are adhered to the sealing member 2. As a result, sealing of the electrolyte layer 1 is reliably conducted.

To satisfactorily seal the electrolyte layer 1 by ultrasonic welding, it is preferable that the substrates 61 and 62, and the sealing member 2 be formed of similar materials. Here, “similar materials” means identical materials or materials having almost the same physical properties such as melting temperature, coefficient of thermal expansion, etc. Preferable examples thereof are, as described above, at least one material selected from the group consisting of polyethylene terephthalate (PET), silicone-based resins, fluorine-based resins, and acrylic-based resins. Among theses, polyethylene terephthalate is particularly preferable.

The fact that the melting depth and rise time during ultrasonic welding greatly affect the performance of a cell (photoelectric conversion efficiency, sealability) was discovered in the experiment as described later that was conducted by the present inventors. It is possible to easily set up the melting conditions for acquiring a desired melting depth and rise time by using the similar materials for the substrates 61 and 62 and sealing member 2.

Here, “melting depth” means the indentation depth of the horn 8 when the position where the horn 8 initially contacts the substrate 62 is defined as a reference point. If the melting depth is unduly small, satisfactory sealing cannot be obtained, while if the melting depth is unduly large, the conductive connecting parts 41 and 51 are damaged and the photoelectric conversion efficiency may be impaired. “Rise time” means the duration of time from starting application of ultrasonic oscillation until reaching the maximum output by substantially linearly increasing the oscillational energy. If the rise time is too short, the conductive connecting parts 41 and 51 are damaged by too rapidly imparted energy, and therefore the photoelectric conversion efficiency may be compromised. Accordingly, by selecting suitable melting depth and rise time while taking the materials and the thicknesses of the substrates and sealing member into consideration, it is possible to obtain excellent sealability and photoelectric conversion efficiency. As a result, it becomes possible to maintain excellent cell performance for a long period. Specifically, it is preferable that the relative melting depth be 0.3 to 0.6, provided that the total thickness of the first substrate, the sealing member and the second substrate is defined as 1. The rise time is preferably not less than 0.1 second. Note that if the rise time is too long, production efficiency may be impaired, and therefore the rise time is practically preferably not longer than 0.5 second.

One embodiment of the present invention is explained above; however, embodiments of the present invention are not limited to this. For example, in the method for manufacturing the photovoltaic cell of the present embodiment, the substrates 61 and 62 are ultrasonically welded after forming the electrolyte layer 1; however, it is also possible to subject the substrates 61 and 62 having the sealing member 2 in between to ultrasonic welding, and then to form the electrolyte layer 1 by injecting an electrolytic solution between the substrates 61 and 62 through an inlet (not shown), etc.

### EXAMPLE

The present invention is explained in detail with reference to an Example. However, the present invention is not limited to the below-described Example.

### Example 1

A 100 μm thick polyethylene terephthalate (PET) film, with a conductive layer 5 made of ITO formed on the surface thereof, was used as a substrate 61, and a 30 μm thick sealing member 2 made of PET was disposed on the conductive layer 5. Subsequently, a titanium oxide sol (product name: “P-25”, manufactured by Nippon Aerosil Co., Ltd.) was applied in the openings of the sealing member 2, and dried, obtaining a semiconductor electrode 7 formed from a titanium oxide porous film. Thereafter, the surface of the semiconductor electrode 7 was dipped in a sensitizing dye solution for several minutes and dried, the photosensitizing dye thereby being supported by the semiconductor electrode 7. Subsequently, an acetonitrile-based electrolytic solution was applied on the semiconductor electrode 7 to form an electrolyte layer 1.

A 100 μm thick PET film with a counter electrode 4 formed by sputtering platinum thereon was used as a substrate 62, and the counter electrode 4 was placed on the electrolyte layer 1. The portions where the three layers, i.e., the substrate 61, the sealing member 2, and the substrate 62, overlap were subjected to ultrasonic welding using an ultrasonic welding apparatus as shown in FIG. 2 to seal the electrolyte layer 1, obtaining a parallel module of a dye-sensitized solar cell having a structure as shown in FIG. 1.

Cell performances and sealabilities were measured under various welding conditions for ultrasonically welding substrates 61 and 62. Table 1 shows the results.

TABLE 1

| Welding Conditions | | | | Cell performance | |
|---|---|---|---|---|---|
| Melting | Rise | Maximum | | Photoelectric | |
| depth | time | output | Output | conversion | |
| (μm) | (s) | (W) | (J) | efficiency | Sealability |
| 30 | 0.025 | 955 | 14.9 | 0 | Bad |
| 60 | | 979 | 45.0 | 0 | Bad |
| 90 | | 968 | 58.8 | 6 | Good |
| 90 | 0.100 | 1003 | 58.9 | 10 | Good |
| 120 | 0.025 | 1023 | 80.3 | 5 | Good |
| 150 | | 983 | 255.9 | 1 | Good |

In Table 1, “maximum output” means the maximum instantaneous energy (W) that the horn gave to the welded portions. “Output” means total energy (J) that the horn gave to the welded portions. Output was determined by pressing pressure of the horn, welding time, and amplitude. The “melting depth” was determined mostly by the “output”, so that a desired “melting depth” can be obtained by controlling the “output”. Furthermore, the “photoelectric conversion efficiency” was measured by irradiating artificial sunlight (spectral distribution: AM 1.5, irradiance: 100 mW/cm²) and is shown as a relative value when the “photoelectric conversion efficiency” at a melting depth of 150 μm was defined as 1. “Sealability” was evaluated by the occurrence of leakage of liquid from the electrolyte layer 1 one month after the production.

As is clear from Table 1, when the melting depth was unsatisfactory, satisfactory sealing of the electrolyte layer 1 was not achieved, and this caused leakage of the electrolytic solution. In contrast, when the melting depth was too great, although satisfactory sealing was obtained, cell performance tended to be poor. Furthermore, the relationship between the rise time and the cell performance at a melting depth of 90 μm was examined. When the rise time was prolonged, excellent sealability was maintained and the photoelectric conversion efficiency was further improved. In the present Example, preferable welding conditions are such that the melting depth is 90 to 120 μm (i.e., when the total thickness of the first substrate, the sealing member and the second substrate (230 μm) is defined as 1, the relative melting depth is approximately 0.3 to 0.6), and the rise time is not less than 0.1 second.

### Comparative Example 1

A photovoltaic cell was produced in the same manner as in Example 1 except that a 30 μm thick ionomer resin (product name: HIMILAN, manufactured by Du Pont-Mitsui Polychemicals Co., Ltd.) was used as a material for the sealing member 2 instead of the PET film, and welding was conducted by thermocompression bonding (130° C., 5 minutes) instead of ultrasonic welding. Leakage of liquid from the electrolyte layer 1 was checked one month after the production. The electrolytic solution had evaporated and the photovoltaic cell did not function as a cell.

### Comparative Example 2

A photovoltaic cell was produced in the same manner as in Example 1 except that a 30 μm thick ionomer resin (product name: HIMILAN, manufactured by Du Pont-Mitsui Polychemicals Co., Ltd.) was used as a material for the sealing member 2 instead of the PET film. The welding conditions for ultrasonic welding were such that the melting depth was 90 μm and the rise time was 0.1 second. Melting of the sealing member 2 occurred to an unduly great extent and the counter electrode 4 and the conductive layer 5 adhered to each other, developing a short circuit. To prevent such a short circuit, the welding conditions were changed to give a melting depth of 60 μm and a rise time of 0.1 second. This resulted in unsatisfactory welding strength, and satisfactory sealability was not obtained.

1. A photovoltaic cell comprising:
a transparent first substrate having a semiconductor electrode supporting a photosensitizing dye;
a second substrate having a counter electrode disposed so as to face the semiconductor electrode; and
an electrolyte layer disposed between the semiconductor electrode and the counter electrode,
the electrolyte layer being sealed by a sealing member lying between the first substrate and the second substrate,
the first substrate, the second substrate and the sealing member being formed of similar materials, and
the portions of the first substrate and the second substrate that are in contact with the sealing member being ultrasonically welded to the sealing member.

2. A photovoltaic cell according to claim 1, wherein the first substrate and the second substrate comprise a plurality of semiconductor electrodes and counter electrodes,
the electrolyte layer is disposed between each pair of semiconductor electrodes and counter electrodes,
each adjacent pair of semiconductor electrodes and each adjacent pair of counter electrodes are electrically connected through conductive connecting parts, and
the sealing member seals each of the electrolyte layer individually.

3. A photovoltaic cell according to claim 1, wherein the first substrate, the second substrate, and the sealing member are formed of at least one material selected from the group consisting of polyethylene terephthalate, silicone-based resins, fluorine-based resins, and acrylic-based resins.

4. A photovoltaic cell according to claim 1, wherein the first substrate, the second substrate and the sealing member are formed of polyethylene terephthalate.

5. A method for manufacturing a photovoltaic cell,
the photovoltaic cell comprising a transparent first substrate having a semiconductor electrode supporting a photosensitizing dye;
a second substrate having a counter electrode disposed so as to face the semiconductor electrode; and
an electrolyte layer disposed between the semiconductor electrode and the counter electrode,
the electrolyte layer being sealed by a sealing member lying between the first substrate and the second substrate,
the first substrate, the second substrate and the sealing member being formed of similar materials, and
the method for manufacturing the photovoltaic cell comprising an ultrasonic welding step for welding the portions of the first substrate and the second substrate in contact with the sealing member to the sealing member.

6. A method for manufacturing a photovoltaic cell according to claim 5, wherein the rise time in the ultrasonic welding step is not less than 0.1 second.

7. A method for manufacturing a photovoltaic cell according to claim 5, wherein the relative melting depth in the ultrasonic welding step is 0.3 to 0.6, provided that the total thickness of the first substrate, the sealing member and the second substrate is defined as 1.
